(19) United States
(12) Patent Application Publication
(10) Pub. No.: US 2007/0207268 A1
(43) Pub. Date: Sep. 6, 2007

(54) Ribbed CVC structures and methods of producing

(76) Inventors: R. Kyle Webb, Escondido, CA (US); Ronald H. Chand, Paxton, MA (US); Clifford Tanaka, Lihue, HI (US); Colby Foss, Kapaa, HI (US)

Correspondence Address: TREX ENTERPRISES CORP., 10455 PACIFIC COURT, SAN DIEGO, CA, 92121, US

(21) Appl. No.: 11/249,860

(22) Filed: Oct. 12, 2005

Related U.S. Application Data
(63) Continuation-in-part of application No. 11/006,044, filed on Dec. 7, 2004.
(60) Provisional application No. 60/527,163, filed on Dec. 8, 2003.
(60) Provisional application No. 60/562,399, filed on Apr. 15, 2004.
(60) Provisional application No. 60/618,405, filed on Oct. 12, 2004.
(60) Provisional application No. 60/618,406, filed on Oct. 12, 2004.
(60) Provisional application No. 60/636,767, filed on Dec. 15, 2004.
(60) Provisional application No. 60/644,916, filed on Jan. 18, 2005.

(51) Int. Cl. C23C 16/26; C23C 16/00

(52) U.S. Cl. 427/249.6; 427/248.1; 427/248.1

(57) ABSTRACT

A process for making a ribbed light weight composite mirror unit. Preferred embodiments are silicon carbide composite structures. Preferred structures comprise a front smooth silicon carbide surface supported by a silicon carbide ribbed back support. The ribbed back support may be produce by milling out portions of SiC block or by the joining of multiple simple shapes to form the ribbed support. At least the smooth front SiC surface is produced using a chemical vapor composite process as described in the Background Section. These include very large mirrors that resist gravitational sagging and smaller scanning and stepping mirrors that can be pointed quickly and accurately with minimal hysteresis. Preferred milling techniques include precision water jet milling. Special bonding techniques are described to produce ribbed support from multiple parts.

### CROSS REFERENCE TO RELATED APPLICATIONS

This application is a continuation in part application of Ser. No. 11/006,044 that claimed the benefit of provisional parent applications Ser. Nos. 60/527,163, filed Dec. 8, 2003, 60/562,399, filed Apr. 15, 2004, 60/618,405 filed Oct. 12, 2004 and Ser. No. 60/618,406 filed Oct. 12, 2004. This application also claims the benefit of Provisional applications Ser. Nos. 60/636,767 filed Dec. 15, 2004, 60/644,916 filed Jan. 18, 2005, and 60/______ filed Sep. 30, 2005. Ser. No. 11/006,044 is incorporated by reference herein.

### FEDERALLY SPONSORED RESEARCH

This invention was made in the course of contract performance under contract with United States government and the United States government has rights in the invention.

### BACKGROUND OF THE INVENTION

The present invention relates to composite materials and especially to light weight rigid silicon carbide chemical vapor composites and to methods of making them.

### Composites

Composites are a class of materials that mix two or more distinct phases generally with the objective of achieving a mixture with improved properties such as improved mechanical or thermal properties. Composite technology has been used in a number of applications such as the production of structural components. For example, metal matrix composites (typically metal particles mixed with a ceramic base) can have desired performance features relating to high-temperature stability, chemical inertness, hardness and toughness. Composite design can also provide other desired properties relating to magnetic, electrical and optical features. It is often important to be able to control the microstructure (grain size and grain distribution). Composites can be produced utilizing high temperature treatment of liquid or solid phase mixtures, but with these processes control of grain size is difficult. In the case of ceramic and other high temperature composites, sintering agents are typically used to promote reactions of the separate components at reasonable temperatures. However, these agents act as impurities that may degrade performance of the resulting composite.

### Chemical Vapor Deposition

The direct application of solid materials to various substrates by chemical vapor deposition (CVD) is well known. For example, methyltrichlorosilane (CH₃SiCl₃) gas decomposes on contact with hot surfaces to SiC (a solid which plates out on the hot surfaces) and gaseous HCl, which is drawn off.

### Chemical Vapor Composites

U.S. Pat. Nos. 5,154,862 and 5,348,765 assigned to Applicants employer describe processes by which a composite article may be formed in a single step process from the coupling of a chemical vapor deposited matrix with a fine particle second phase embedded within the matrix. Such articles are formed at high deposition rates and may obviate the above-described prior art disadvantages. These prior art processes, known as chemical vapor composite (CVC) processes, utilize particles with sizes in the range of about 1 nm to 60 microns or larger with the particle mass comprising about 5 percent of the composite mass or greater, typically about 1 to 10 percent. With these prior art CVC processes deposition rates were much higher than CVD deposition rates but the densities of the resulting products were substantially reduced as compared to similar products produced with CVD processes. Prior art CVC processes utilize relatively small reactors having work zones smaller than one cubic meter. With the limited work zone volume and fact that composite runs generally require at least a few days to complete, the result is high costs of the composite products. In addition, prior art CVC processes have not provided techniques for good control of either composite density or grain size.

### CVC Mirrors

There are known advantages of using silicon carbide structures for large mirrors. Large mirrors typically must be very dimensionally stable and should be relatively light weight. As the mirrors become larger maintaining dimensions becomes more challenging. Also, smaller light weight rigid mirrors that can be moved very quickly are needed.

What is needed light weight rigid ceramic structures and a method of efficiently producing them.

### SUMMARY OF THE INVENTION

### Ribbed Structures

The present invention provides a process for making a ribbed light weight composite mirror unit. Preferred embodiments are silicon carbide composite structures. Preferred structures comprise a front smooth silicon carbide surface supported by a silicon carbide ribbed back support. The ribbed back support may be produce by milling out portions of SiC block or by the joining of multiple simple shapes to form the ribbed support. At least the smooth front SiC surface is produced using a chemical vapor composite process as described in the Background Section. These include very large mirrors that resist gravitational sagging and smaller scanning and stepping mirrors that can be pointed quickly and accurately with minimal hysteresis. Preferred milling techniques include precision water jet milling. Special bonding techniques are described to produce ribbed support from multiple parts.

### Multi-Element Ribbed Supports

Preferrably the ribbed supports may be made form thin sheets of CVC SiC. The sheets are cut into generally rectangular shapes with slots and the slotted rectangular shapes are formed into an egg-crate structure. The egg-crate structure can be bonded firmly together with a CVC deposition or used as is. To make a rib supported mirror empty spaces in the egg-crate are filled in, at least at the top and a thin mirror surface sheet is CVC deposited on top of the egg-crate. A good filler material is graphite in solid form, in sheet form or in powder form. The mirror surface sheet is firmly bound to the egg-crate structure which supports the mirror surface sheet. After deposition of the mirror surface sheet the material filling in the egg-crate spaces may then be removed leaving only the mirror surface sheet supported by the egg-crate structure. This is a light weight strong rigid mirror. Sandwich or I-beam structures can also be made with a variation of this basic technique. CVC sheets are CVC deposited on both top and bottom of the egg-crate structure. Preferably, holes are cut in the egg-crate elements so that material partially or fully filing the empty spaces in the egg-crate can be removed such as by thermally converting graphite filler material to carbon dioxide. CVC egg-crates can also be made by CVC depositing SiC in egg-crate type grooves of a graphite mandril. The graphite can then be burned away leaving the egg-crate on which a CVC sheet can be deposited.

### Milled Ribbed Support

Special techniques are described for milling ribbed silicon carbide support structures from solid silicon block material. Preferred techniques utilize precision water jet cutting and milling processes.

### Chemical Vapor Composites

### Chemical Vapor Deposition with Addition of Particles

The invention is a method for forming, within a reactor having a work zone of at least one cubic meter, composite articles, particularly ceramic composite articles, for high temperature applications. The invention provides composite articles formed from the deposition as a solid matrix on hot surfaces of a chemical vapor having entrained solid particles. A composite material is produced comprising the chemical vapor deposition matrix with the solid particles dispersed within the matrix. By carefully controlling the reactor gas flows and pressure within a large work zone, as well as the number of solid particles per flow rate of reactor gas, Applicants are able to efficiently produce composites with substantially improved quality as compared with CVD produced articles and as compared with articles produced with prior art CVC processes. Preferred embodiments include ribbed SiC structures including large ribbed SiC mirrors.

### Heated Substrates

The reactant gases referred to above must be heated to a temperature high enough to cause decomposition of the gas. A preferred technique is to fabricate an underlying material, a substrate, into a desired shape, such as a coil, wire or a more complex configuration such as a vane, turbo rotor, rocker arm, or other engine component. The shaped substrate is then maintained at the required elevated temperature, thereby providing the thermal activation necessary for the decomposition of the chemical precursor gas. The exact temperature range is dependent upon the ultimate CVD matrix composition selected.

### Precursor Gasses and Particles

A gaseous mixture containing the precursor gas, a carrier gas, and particles of the second phase material is then injected onto and over the heated substrate. The present invention can be utilized with a large number of precursor gasses to produce a variety of matrix materials. In this application 33 separate composite processes have been specifically identified. The particles of solid phase materials can be any of a large number of materials and shapes. Materials such as SiC, Si₃N₄, and ZrO₂ are examples of materials. Preferred shapes include random shaped particles of various mesh sizes, fibers, wiskers, nanoparticles and nanotubes.

### Silicon Carbide

A preferred composite material made by according to the present invention is silicon carbide composite materials. For example, a stream of methyltrichlorosilane and hydrogen is injected into the CVD chamber accompanied by a simultaneous flow of silicon carbide particles of 40-14,000 mesh. The gas mixture with the entrained particles is introduced into the reactor at a relatively low temperature. The CH₃SiCl₃ breaks down into solid SiC and gaseous HCl when the CH₃SiCl₃ gas contacts very hot surfaces in the reactor. The SiC along with some of the entrained particles deposits on the hot surfaces in the reactor, in particular graphite substrates having the general shape of desired articles. Gaseous HCl and hydrogen are pumped out of the reactor and disposed of. When desired thicknesses of the SiC-particle composite have been deposited, the reactor is cooled and the substrate with the coating of SiC-particle matrix is removed from the reactor. The substrate may then be removed leaving the SiC-particle composite article having qualities substantially superior to SiC deposited utilizing conventional CVD processes. The coated article thus produced contains a shaped underlying substrate fused to a CVD produced silicon carbide matrix having a uniform and random distribution of silicon carbide particles embedded therein.

### Large Reactor

Preferably, the reactor should have a work zone of at least one cubic meter for efficient production of a large number of small composite articles or the production of a smaller number of large items. A vertically oriented reactor is described with a cylindrical work zone 64 inches high and a diameter of 64 inches providing a work zone volume of 3.37 cubic meters and permitting production of large products or simultaneous production of a large number of small products. Large horizontally oriented reactors are also described specifically designed for the production of tubular shaped ceramic composites.

### BRIEF DESCRIPTION OF THE DRAWINGS

FIG. 1 is a side cross section view of a large reactor chamber showing important internal components;

FIG. 2 is a top cross section view of the reactor of FIG. 1;

FIG. 3 shows the heating elements of the reactor;

FIG. 3A shows a single heating element;

FIG. 4 is a drawing showing the flow of reactor gases and waste gas.

FIGS. 5A and 5B are side cross section views of important components of a preferred embodiment of the present invention.

FIG. 5C is a top cross section view of the components of the preferred embodiment.

FIG. 6 shows a technique for making 14 mirror blanks at the same time.

FIGS. 7 and 8 show an egg-crate structure.

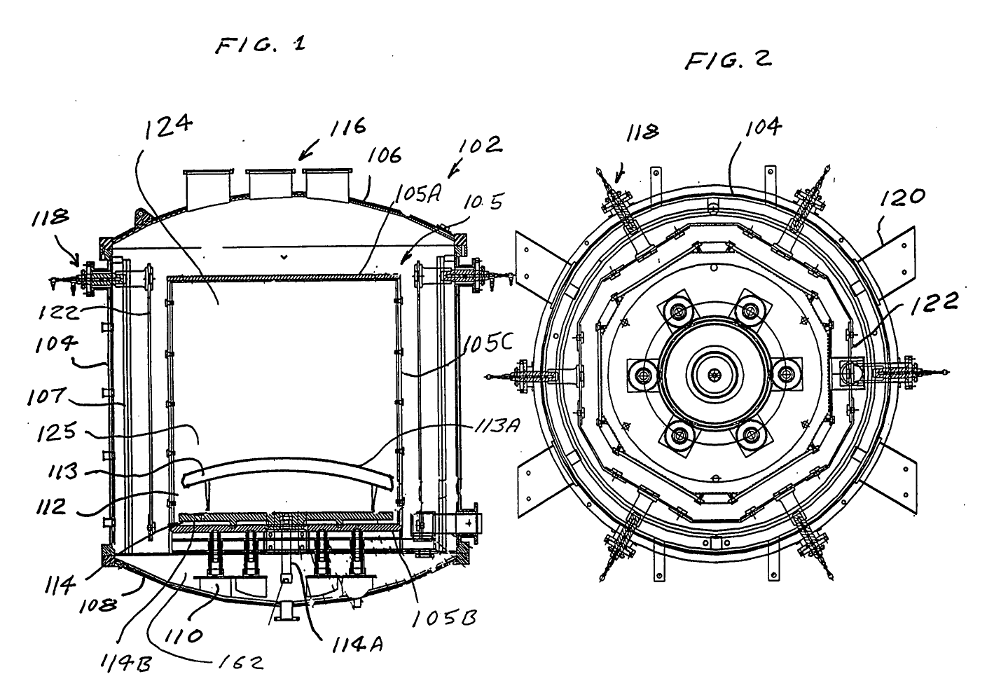

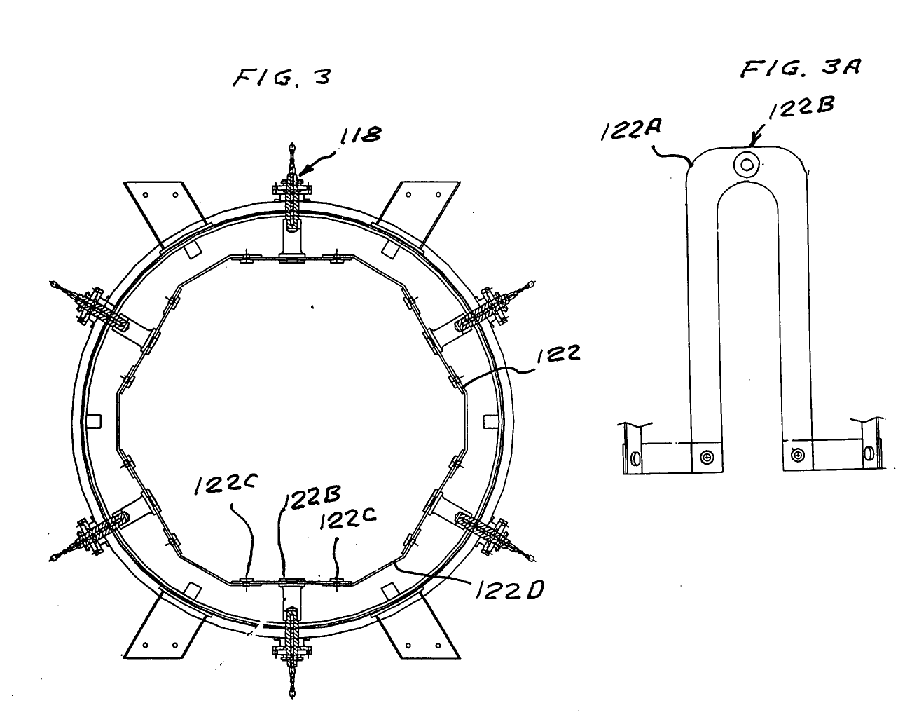

### DETAILED DESCRIPTION OF PREFERRED EMBODIMENTS

### Chemical Vapor Composite Process

### The Basic Process

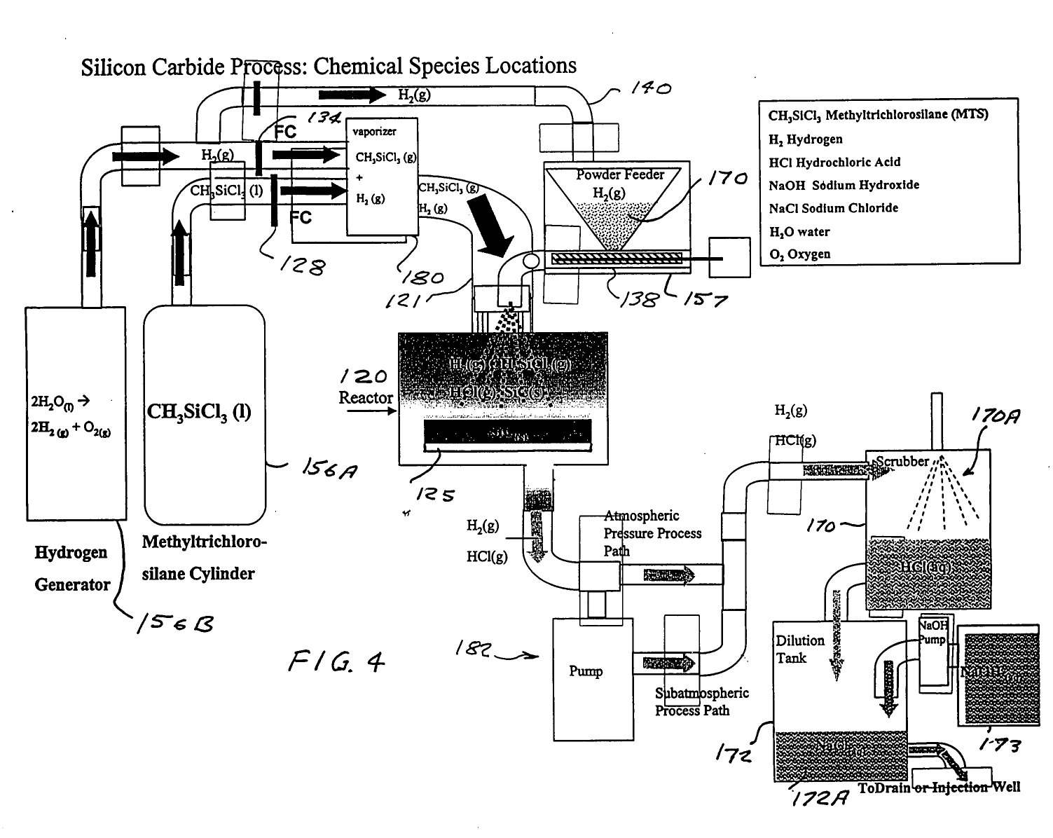

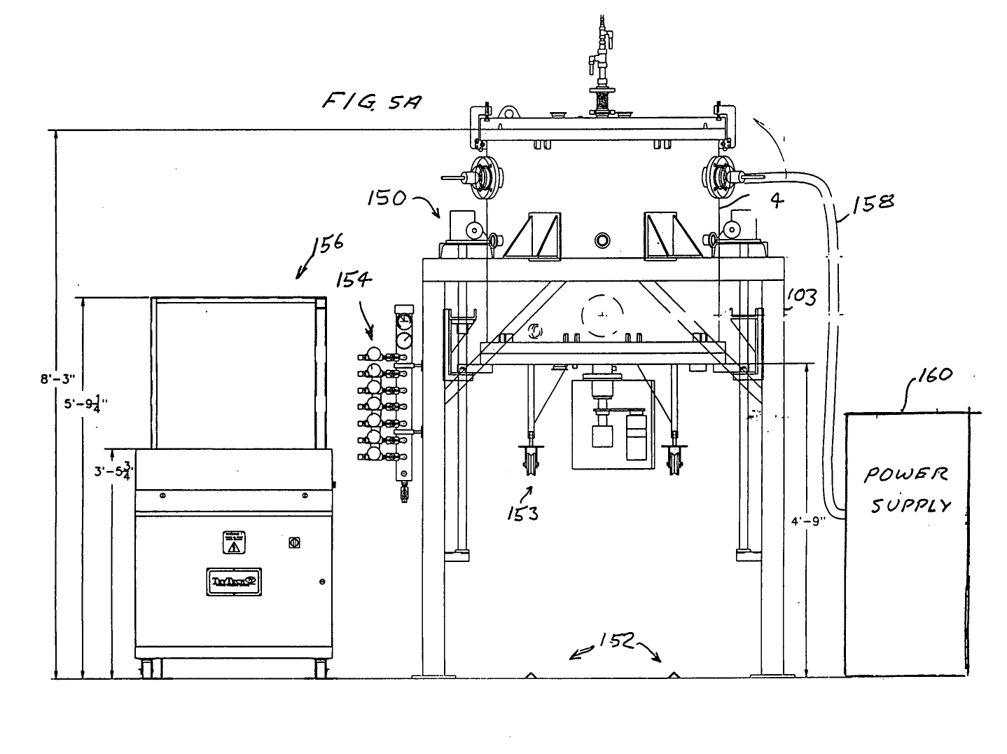

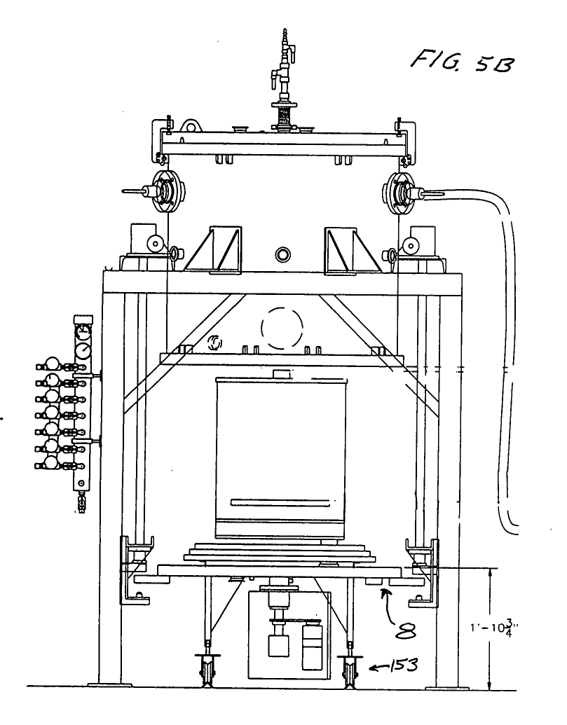

FIG. 4 is a drawing showing the basic elements utilized in preferred embodiments of the present invention. In this example, liquid CH₃SiCl₃ from source tank 156A is mixed with hydrogen from hydrogen generator 156B in vaporizer 156C where the liquid CH₃SiCl₃ is vaporized. Fine particles 170 from powder feeder 157 are driven by auger 157A and hydrogen pressure into the flow stream of the two feed gases CH₃SiCl₃ and hydrogen. Substrate 125 in reactor 102 is heated to temperatures in the range of 1200-1800 degrees C. When the CH₃SiCl₃ gas contacts the hot substrate, the gas is broken down to solid SiC which plates out on hot surfaces of the substrate as polycrystalline silicon carbide with the particles dispersed in a SiC vapor deposit matrix to form a silicon carbide composite layer having a polycrystalline silicon carbide matrix containing the fine particles. HCl is released as a gas. The HCl gas is trapped in scrubber 171 where it is mixed with spray water from spray 171A and converted to aqueous hydrochloric acid 171B which in turn is reacted with a sodium hydroxide solution from tank 173 to produce salt water (NaCl_{(aq)}) 172A in tank 172. The salt water is disposed of.

### The Reactor Chamber

FIG. 1 shows a side view of a cross section of a reactor chamber 102 utilized in preferred embodiments of the present invention.

Reactor Shell

A reactor shell is comprised of a 304L stainless steel cylinder 104, a rounded stainless steel top cover 106 and a rounded stainless steel bottom cover 108. The cylinder and both top and bottom covers utilize a double wall design. A 10 psig pressure relief device is provided on the chamber. Six power ports 118 are provided to accommodate electric power feed through assemblies for the heating elements 122. Twelve additional ports (not shown) are provided for the installation of instrumentation and control components. A water-cooled exhaust port is also provided on the chamber. The reactor shell is equipped with a cooling water jacket providing cooling water flow in the spaces between the two walls of the shell. The outside wall temperature of the reactor is maintained at about 25-35 degrees C. when internal work zone temperatures are at about 1400 degrees C. Thermal insulation consists of 2 inches of carbon felt on the side of the hot zone, and 3 inches of insulation on the top and bottom of the hot zone. The carbon felt is mounted on the inner surface of a stainless steel support cage assembly 107. Cooling water manifolds incorporating shut off capability on both the supply and return side are mounted to the chamber support frame. Flow sensors with adjustable minimum level settings are provided for each cooling circuit. Interlocks are provided for connection to the power supply and alarms.

Heat and Pressure

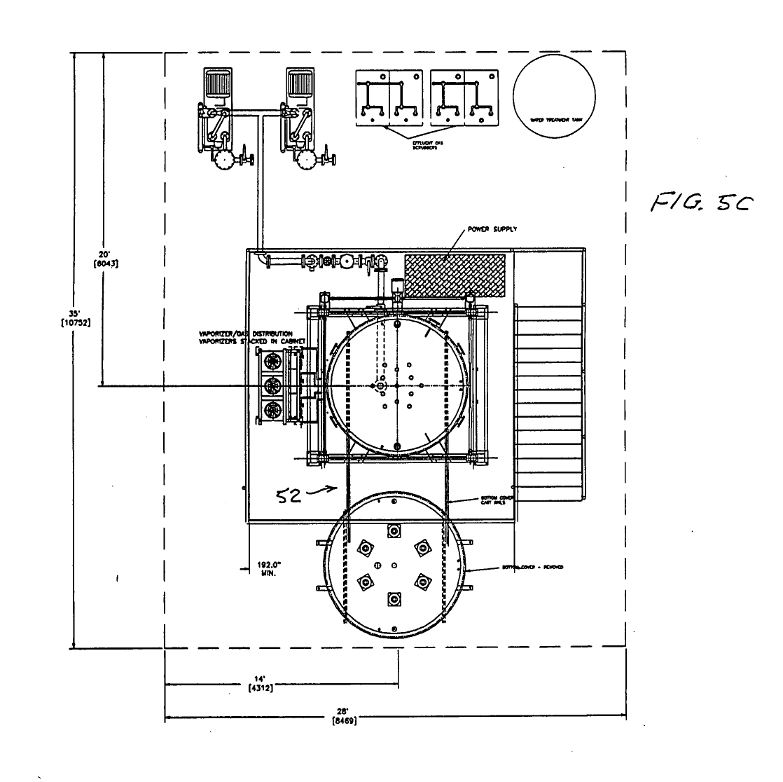

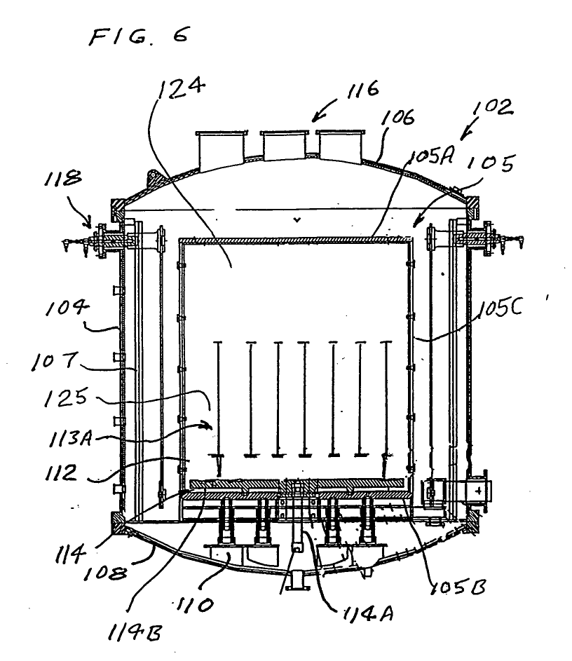

In preferred embodiments graphite heating elements 122 in reactor 102 heat the internal components of the reactor and the substrate material to temperatures of about 1200-1500 degrees C. prior to the injection of the feed gas—particle mix. Heating elements 122 are a three-phase resistance configuration for a balanced electrical loading. A modular design is utilized for easy part replacement during maintenance cycles to minimize downtime. A total of six water-cooled power feed through assemblies 118 are connected to the six graphite heating elements. A VRT type, low voltage, three phase power supply 160 as shown in FIG. 5A supplies power to heating elements 122 via water-cooled power cables 158. Micarta flanges provide electrical insulation from the grounded furnace chamber. A steady state holding power is approximately 170 KW, (excluding losses from gas flows). Power supply 160 comprises a 300 kva transformer to provide a 4-hour heat up time. The feed gas is preferably at about room temperature—is heated very rapidly when it comes in contact with hot (e.g., about 1400 degrees C.) surfaces within the work zone including the hot graphite substrate 113. The high temperature causes the CH₃SiCl₃ to breaks down into SiC and HCl. The SiC along with some of the entrained particles deposits out on surfaces in the reactor, especially the graphite substrate 113. The internal components of the reactor are preferably graphite with carbon felt insulation. The reactor is capable of operation at temperatures up to 1600 degrees C. The typical heat up rate is 4 hours from room temp to 1400° C. Prior to operation the reactor pressure is drawn down to a vacuum of 1 torr with pump 142. This process takes about 60 minutes with pump 42 sized for about 300 atmospheric cubic feet per minute. Reactor vessel integrity is important. The chamber should be capable of passing a 10⁻⁶ standard cc/sec helium leak test.

Work Zone Enclosure

The chamber provides a 64 inch internal diameter, 64 inches high work zone 124 providing a volumetric work zone of about 3.37 cubic meters. The work zone is surrounded by a graphite enclosure 105 consisting of a bottom cover 105B, top cover 105A, and a graphite tube 105C assembly to keep the heating elements and thermal insulation clean to minimize maintenance. A uniquely designed exhaust region is included to minimize both un-reacted process gases and pyrophoric reactant byproduct downstream. The exhaust region is a subsidiary graphite compartment below the main chamber, separated by a graphite plate with between 6-12 exhaust holes. This compartment directs the exhaust gases to the exhaust plumbing along hot graphite surfaces which help to completely react any un-reacted pre-cursor gases or partially reacted subsidiary byproducts. The work zone enclosure and the bottom portion of the insulation can be lowered together with the bottom cover to allow easy access as shown in FIGS. 6A and 6B. Rotational mechanism 114 with shaft 114A is provided to achieve maximum deposition uniformity by rotating turntable 114B at rates of 0 to 10 rpm. The mechanism is capable of supporting up to 10,000 pounds. The large graphite components are preferably fabricated from PGX or CS grade graphite. CS grade components are incorporated in the chamber.

Reactor Frame

A steel frame 103, as shown in FIG. 5A supports the chamber, and a bottom cover lifting mechanism 150. Substrates on which composites are to be deposited are loaded into and unloaded from the work zone 124 through the bottom of the chamber as shown in FIGS. 5A and 5B. Frame 103 supports the reactor shell 4 at an elevated position and bottom cover 108 which can be lowered and raised with lifting mechanism 150. The bottom cover is lifted to the closed, operating position by an electrically operated lifting device mounted on the chamber support frame for stability and repeatable positioning. Location pins provided on the lifting mechanism ensures consistent proper alignment. The bottom cover may be rolled away from frame 103 from its lower position on “V” shaped wheels 153 rolling on railway system 152 (as shown in FIGS. 6A and 6B) that is mounted on the floor. Safe, efficient loading and unloading can be achieved via full 360 degree accessibility to the assembly when rolled away from the chamber.

Vapor Delivery System

A vapor delivery system consists of seven methyltrichlorosilane vaporizers 180 (with a total capacity of over 100 lbs/hr) and a gas flow distribution/measurement system, with safety interlocks and shut-off devices. Connections are provided for tie-ins to a liquid MTS source 156A, bulk hydrogen source 156B, bulk argon source (not shown), and utilities. Porter/Bronkhorst Mass flow controllers are included to provide accurate measurement and flow-control for consistent product quality. Seven injectors and interconnect piping are also included. Components of the vapor delivery system are enclosed in a ventilated hood (not shown). The pumping system is designed for extremely corrosive applications and is connected to a vacuum chamber 162 (as shown in FIG. 1) above the bottom cover through a manifold and air operated gate valves. The vacuum pump package is shown as a single pump in FIG. 4 but may consist of dual pumps. This vacuum pump package provides the process flow and is also used for purging and leak checking. Oil filtration and interlocks prevent oil back-streaming. A local pump control panel (not shown) will house the motor starters and heater overloads, and an interface to the main control for interlocks.

Instrumentation

Field instruments include 3 type C thermocouples for furnace temperature control, 7 type K thermocouples for vaporizer control, 14 mass flow controllers, 7 scales for vaporizers, 7 MTS mass flow controllers, 2 pressure transducers, 16 water flow switches and 4 local pressure gauges in the vaporizer cabinet. A PC based (LabView) control system is integrated into the system. The flow of CH₃SiCl₃ gas into reactor is monitored very accurately by measuring the flow rate of liquid CH₃SiCl₃ in the vaporizers.

Substrates

Silicon carbide composite parts are typically produced in reactor 102 by depositing the composites on graphite substrates having the general shape of the desired article to be produced. For example, as shown in FIG. 1, substrate 113 is a substrate for the making of a concave silicon carbide composite mirror. The top surface 113A of the graphite substrate is finely shaped and polished to the inverse of the shape of the desired mirror surface. After a sufficiently thick layer of silicon carbide is deposited on the substrate the substrate with its coating of silicon carbide is removed and the graphite is separated from the silicon carbide mirror. This mirror has a concave surface that may require very little polishing to produce the finished mirror. Differences in thermal contraction make the separation easy. For some shapes where the separation is not automatic or easy, the graphite substrate may be burned away.

Any material may be selected as the underlying substrates so long as it does not decompose at the required CVD temperature nor become subject to chemical reaction with the reactants or products of the process. It should be noted in this regard that the desired decomposition of CH₃SiCl₃ occurs at a temperatures greater than about 1300 degrees C., producing highly corrosive hydrochloric acid which can easily etch a plethora of common substrate materials. However, since the process of the invention is not solely directed at the decomposition of CH₃SiCl₃ into silicon carbide, but instead can be used with any matrix which can be produced through chemical vapor deposition, there will be a plurality of embodiments in which less corrosive gases will be produced at less elevated temperatures. In such embodiments, a broad range of materials may be incorporated as the underlying substrate without resulting in decomposition or corrosion during application of the disclosed process.

### Process Details

FIG. 4 shows the basic elements of a basic preferred process. A working gas CH₃SiCl₃ in a liquid form is pumped from tank 156A through flow control element 128 to vaporizer 180 where the CH₃SiCl₃ is vaporized and mixed with hydrogen gas. The hydrogen gas is produced by electrolytic separation of water in hydrogen gas generator 156B (Model HM 200, available from Teledyne Energy Systems) and the flow of hydrogen is controlled with flow control element 134. A typical feed gas flow would be about 400 standard liters per minute at about atmospheric pressure. The typical feed gas is 15 percent CH₃SiCl₃ and 85 percent hydrogen. Particles are added to the feed gas flow as shown in FIG. 4. Particles from particle feeder 170 are added at a controlled rate with auger 138 with some assist produced by a small pressure of hydrogen gas from gas pipe 140. A typical particle flow would be 50 grams per minute of SiC particles.

### Reactant Gasses

As described above, a preferred reactant gas employed in the formation of composite articles according to the invention is a mixture of methyltrichlorosilane (donor gas) and hydrogen (carrier gas), and a preferred particle material is silicon carbide. The mixture of reactant gas and entrained particles is made by introducing the particles and a carrier gas such as hydrogen from a powder feeder 157 into a stream of reactant gas carried by the line 121. The reactant gas and particles typically are supplied to the reactor 120 at or slightly (about 10 to 20 degrees C.) above room temperature. A continuous flow of particles from the feeder 157 is typically utilized to ensure a uniform build-up both of the CVD matrix produced from thermal activation of the reactant gas and of the particles which are co-deposited with the matrix. The particles may include long or short particles, or both, with selection dependent on the desired application of the composite article. Silicon carbide particles of 325-600 mesh size (dimensions of about 2 mils) have been found to be especially suitable in forming composite tubes.

### Alternative Gasses

In alternative embodiments precursor gases other than methyltrichlorosilane may be used to produce the SiC composite article of interest, provided a carbon containing precursor gas (e.g. hydrocarbons such as methane, propane, butane, etc.) and a silicon containing precursor gas (e.g., SiH₄, SiCl₄, SiHₓCl₄₋ₓ, etc.) are included. Reaction temperatures in these cases may range between about 800 to 1350 degrees C. For matrixes other than SiC as discussed in more detail below, the precursor gasses used are preferably those typically used in normal CVD processes to produce the matrix material.

### Ribbed Structures

Rib supported structures for large mirrors and other lightweight/stiff structures are now described:

Multiple Depositions

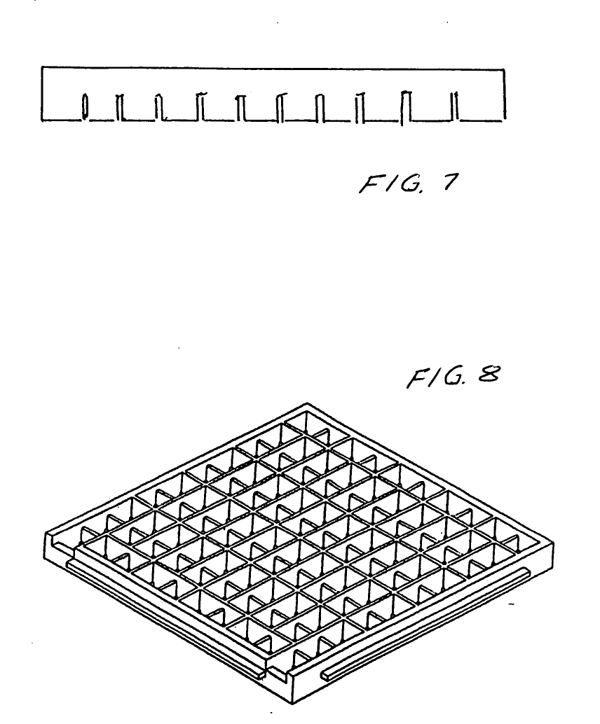

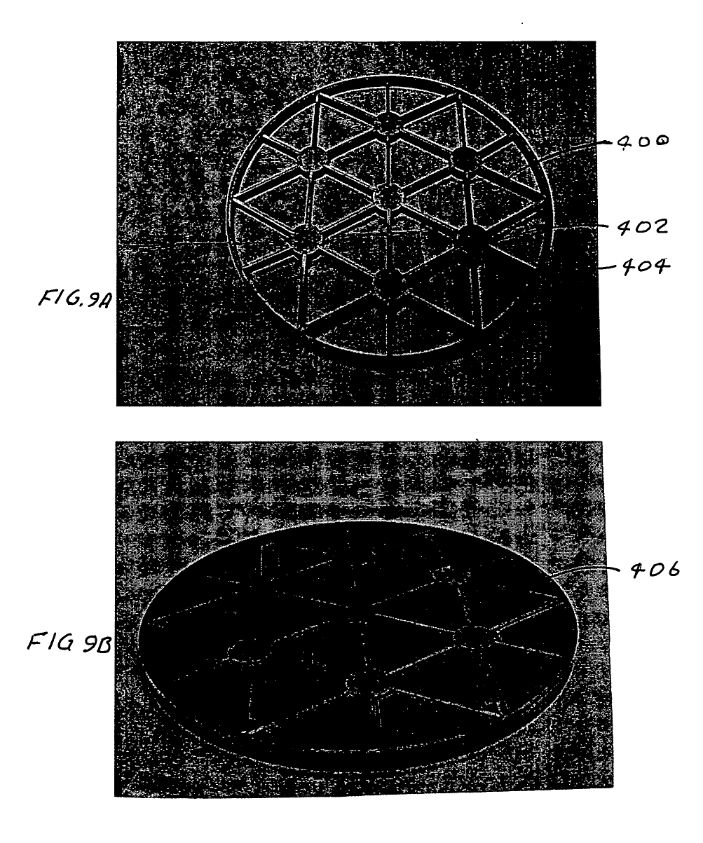

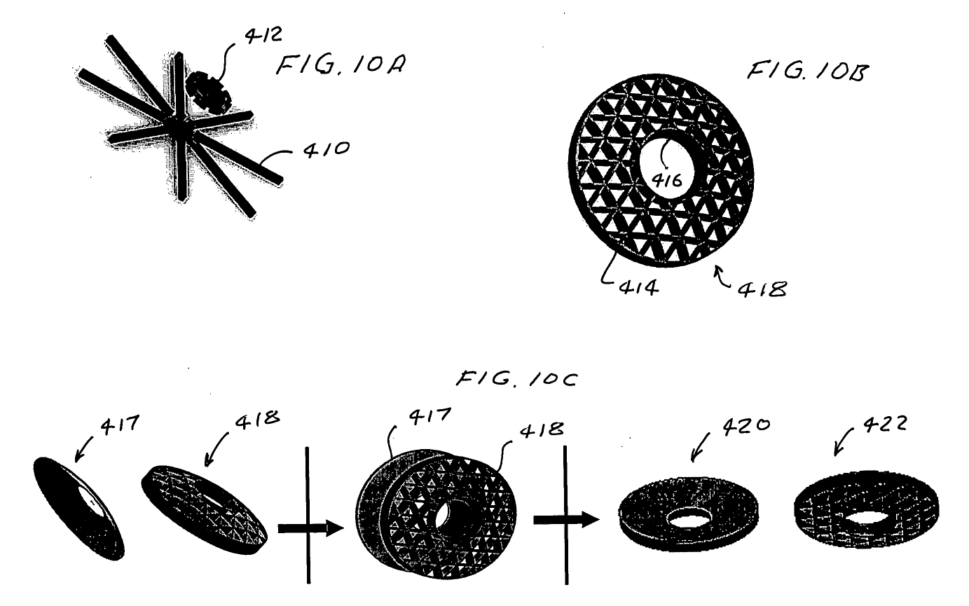

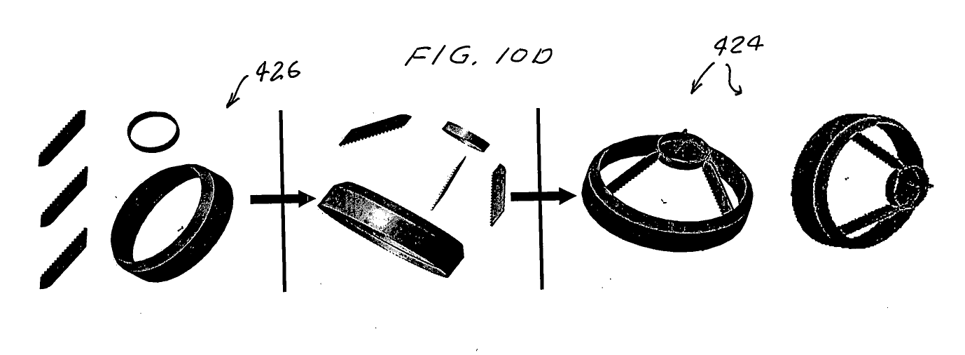

The ribbed structure can be fabricated from a thin sheet of CVC SiC. The sheet would be machined as indicated in FIG. 7 and several of the machined sheets assembled to form an egg crate type of structure as shown in FIG. 8. The ribbed structure can then be bonded together with a second CVC SiC deposition or used as is. The ribbed structure would then be loaded into the reactor for another deposition with the holes/openings blocked out. The blocking can be done by any material, in powder form, solid blocks, or sheets, e.g. graphite powder, graphoil structures, or solid graphite plugs etc. Then the structure will be coated to form an upper layer that would be suitable for a mirror application etc. After deposition, the filling material can be removed to form a near net shape CVC SiC structure

If needed, the technique can be used to form sandwich or I-beam type structures. In this instance, the rib material would have holes machined through the ribbing. These holes would create an interconnected open structure between each of the pockets. After the first closing deposition, the coated structure would be inverted and the second surface closed off. Once completed, either the pocket filling material would be removed. (e.g. it could be converted to carbon dioxide thermally or the powder could be vibrated out of the interstices). An advantage of filling in the rib structure with loose fitting solid material is that any overspray would serve to bond or stiffen the ribbed structure.

Composite SiC Structures

A similarly ribbed structure can be fabricated by using another SiC ribbed structure as the base for deposition. This structure could be a sintered SiC, reaction bonded SiC, Poco's SuperSiC, etc. The advantage of this technique is that these other forming techniques can make the ribbed structure through a powder process and any machining can be done in the green state. After the ribbed design if fabricated, the openings can be filled, as above, and a CVC SiC layer deposited on the upper and/or lower surface.

### Preferred Methods for Making Ribbed Mirrors

Two referred methods for making ribbed mirrors can be described by reference to FIGS. 9A and B and 10A-D.

FIG. 9A shows a rib structure formed with ribs 400, slotted hubs 402 and rim 404. These elements are joined in a multi-metal bonding process. Preferably the metals are titanium, platinum, gold and a tin based solder. Once the rib structure is formed graphite spacers 406 are inserted as shown in FIG. 9B, then the assembly is placed in the CVC reactor and a CVC SiC coating about 2 millimeters thick is deposited on the assembly. The spacers are removed and the surface of the mirror is polished. An alternative is to delete the multi-metal bonding step and rely on the CVC coating step to bond the parts of the rib structure together.

In another approach shown in FIGS. 10A-D to provide a Cassegrain mirror unit, a rib structure 418 shown in FIG. 10B is produced using ribs 410, slotted hubs 412, outer rim 414 and inner rim 416. In this case a concave mirror 417 is produced separately in the CVC reactor and is bonded, using the above multi-metal bonding technique, to the rib structure 418. The front of the primary mirror is shown at 420 and the rear at 422. Support structure 424 for the mirror unit is fabricated from SiC parts shown at 426 using the same multi-metal bonding approach.

### Water Jet Milling

Another technique for making light weight rigid SiC ribbed mirrors utilizes a milling process to produce ribbed structures such as those shown in FIGS. 9A and 10B except the ribbed structure is produced from a solid block of SiC. This milling may be done with conventional machine milling techniques. In a preferred embodiment Applicants utilize water jet milling to produce the ribbed structure. Also, instead of making the rib structure separate form the mirror surface as shown in FIGS. 9A and 10B, Applicant have produced ribbed SiC mirror units by milling out the spaces between the ribs with the mirror portion of the SiC block in place. Once the rib structure is formed in the milling process, the opposite surface is polished to produce the mirror surface. This provides a light weight. SiC mirror from a single block with no internal joints.

### CVC SiC Fastener Method

A method of fasting can be fashioned for CVC SiC by implementing low expansion carpenter Fe-39Ni material. Fe-39Ni material has the same approximate thermal expansion characteristics as CVC SiC. If a cylindrical plug shaped feature is created from Fe-39Ni and is plated with Ti—Pt—Au—Sb it can be soldered into a mating hole in CVC SiC that is also has plated with Ti—Pt—Au—Sb. The Fe-39Ni plug can then be welded or soldered by elevating temperature to the melting point of the tin (Sb) thereby forming a single piece. The Fe-39Ni insert can then be drilled and tapped to make a fastener feature.

Single Deposition

Using a grooved mandrel structure and proper selection of the flow and pressure parameters, we can fill in the grooves of a mandrel (graphite) to form the ribbed structure and then close off the upper surface. Alternatively, we can deposit the optical surface onto a mandrel (retaining the near net shape capability). We would then remove the structure from the reactor, place the grooved graphite structure onto the surface, and fill in the grooves. In either case, the “grooved blocking structure” could then be removed, thermally, mechanically, or chemically.

### Composite Coatings on Products

CVD produced material with solid particles suspended therein has been successfully deposited onto flat, square, rectangular, cylindrical, and spherical substrates. These composite layers of CVD matrix and particles uniformly and randomly disposed within the matrix provide a hard, impact and corrosion-resistant covering for otherwise soft materials which are readily susceptible to chemical attack. Hence, relatively common materials such as tungsten, molybdenum and carbon can be manufactured into a final desired embodiment and then subjected to coating with silicon carbide composite utilizing one of the above disclosed methods. The result is a relatively inexpensive produce with an extremely hard, chemically resistant product.

### CVC Products Other than SiC

The present invention is not limited to a specific CVC produced material, such as CVC silicon carbide, but could additionally include other carbides (HfC, TaC, WC, B₄C, etc.), nitrides (Si₃N₄, BN, HfN, AlN, etc.), oxides (SiO₂, Al₂O₃, HfO₂, Ta₂O₅, TiO₂, BaTiO₃, SrTiO₃), silicides (WSi₂, TiSi₂, etc.), and metals (Cu, Al, W, Fe, etc.). Thus the scope of the matrix material which can be produced by the present invention is limited only by the capability of the chemical vapor deposition process to produce the desired chemical composition. However, the present invention provides for the addition of particles as described above that are deposited along with the vapor deposited material. Examples of matrix materials that can be produced utilizing the principals of the present invention are listed in the Table I from U.S. patent application Ser. No. 11/006,044 (incorporated by reference herein) which includes preferred precursor gasses as well as preferred solid particulate materials.

### Control of Deposit Density/Porosity

The incorporation of particles can lead to porosity in the deposit due to incomplete formation of the CVD matrix around the particles. Applicants have discovered that this porosity depends on the feed rate of particulate compared to the CVD matrix growth rate. The porosity of the CVC deposit can thus be controlled by adjusting the feed rate of the particulate from a fully dense deposit to a deposit with as much as 40% porosity, as desired by the specific application. Other deposition parameters also play a role by affecting the CVD matrix growth, including pressure, gas flows and substrate temperatures.

### Rate of Deposition

It is an important advantage of the invention that this co-deposition occurs at a high rate—e.g., 10-20 mils/hour as contrasted with about 2-5 mils/hour in a conventional process depositing silicon carbide by CVD only. Conventional CVD requires the use of low growth rates to minimize internal stress levels. The distinct grain structure afforded by the additional of particles results in a low stress deposit enabling much higher reactant feed rates than is achievable by conventional CVD.

### Preheating of Solid Phase Material

In an alternative arrangement according to the invention the solid phase material and carrier gas are directed to reactor the along a line separate from the line carrying the reactant gas. A pre-heater is included between the feeder and the reactor to heat the solid phase material to a selected temperature; e.g., to a temperature as high as the deposition temperature of the substrate within the reactor. Also a suitable device for mixing the solid phase material and reactant gas within the reactor may be provided as part of this alternative arrangement. Such preheating of the particles or fibers prior to their introduction into the reactor enhances the thermal activation of the reactor gas in the reactor and may produce higher deposition rates, greater uniformity of the composite material, and/or enhanced mechanical properties of the resulting composite article than are achievable by use of a single stream of reactant gas and solid phase material. In this regard it should be noted that preheating of a combined stream of reactant gas and entrained solid phase material would be limited by the need to avoid premature thermal activation of the reactant gas which could lead to deposition in, and clogging of, a supply line or injection nozzle through which the reactants were supplied to the reactor.

### Use of Nanoparticles

Particles with at least one dimension in the range of a few nanometers to a few tens of nanometers (called nanoparticles) may be substituted for the 30 micron particles referred to in the above descriptions. The nanoparticles may be carbon nanotubes, or nanotubes formed from silicon carbide or other metal carbides. Use of these nanoparticles in place of the much larger particles permit a very large increase in the number of particles for the same particle percentage in the resulting composite. Since the composite grain size is determined by the number of particles per composite volume, the larger number of particles mean smaller grain size. Applicants have determined that smaller grain size results in increased fracture toughness. Therefore, these ceramic nanocomposites have greater toughness than composites formed using larger particles or fibers. In addition, the use of nanoparticles can result in unique electrical and optical properties, for example, due to the phenomenon of quantum confinement. The deposition method is applicable to any ceramic material currently obtainable via a CVD process. Carbon nanotubes are known for their extremely high tensile strength, and therefore these nanotubes should engender high strength properties for the CVC phase, where the matrix may be silicon carbide, silicon nitride, or any other phase that can be derived via chemical vapor deposition.

### Reactor Generated Particles

Another preferred variation is one in which particles are generated within the CVD reactor itself, which are then incorporated within the CVD material. In doing so, the same stress relief as the CVC process is accomplished without the need for additional particles to the gas stream. The advantages achieved are higher purity and simplification of the reactor design, while maintaining high density, good mechanical properties, and high growth rates. Methyltrichlorosilane is preferably used as the reactant precursor for the growth of silicon carbide via CVD. MTS vapor is injected into a high temperature furnace at about 1300-1400° C. using a carrier gas of hydrogen. The SiC is deposited on a graphite perform, while simultaneously, SiC particulates are generated above the part. The furnace and preform are designed in the former process to lengthen the residence time of the chemical in the high temperature reaction zone. This serves to increase the probability of SiC particles nucleating from the gas phase. Through control over the pressure, temperature, and feed rates of MTS and H₂, the degree of particle formation can be controlled. Optimization of these parameters yields the desired amount of stress relief, while maintaining fully dense, low porosity material.

The technique can also be applied to other materials, including other carbides, nitrides, oxides, suicides and metals. There are a number of applications, which can benefit from the high purity, low porosity, low stress, and high mechanical strength of the ceramic materials deposited via this technique. Examples of these applications include optics, high purity chemical processes, and components for extreme high temperature environments.

### Controlling Molecular Ratios with CVC Process

The chemical vapor composites method involves the addition of solid particulates (normally polycrystalline silicon carbide particles) to a chemical vapor deposition reaction stream. Molecular ratios can be varied using special process variations of the basic CVC process. In preferred embodiments particles other than polycrystalline silicon carbide can be added to the feed gas stream. These alternative added particles could include various forms of silicon carbide other than polycrystalline silicon carbide; single crystal silicon particles could be used, or mixtures of silicon carbide particles and silicon particles could be used. Also, the matrix material could be altered by using variations in the feed gas. For example, softer optical surfaces may be produced for mirrors that are more amenable to polishing. Thus, for the mirror substrate shown in FIG. 1, a preferred technique is to chemical vapor deposit a few microns thick layer of silicon using tetrachlorosilane gas (SiCl₄) in place of the CH₃SiCl₃ gas in the feed gas for the first few minutes of the deposition process. After the thin layer of silicon is laid down without particles, the active feed gas is switched to CH₃SiCl₃ to lay down the silicon carbide composite material. In some cases a combination of SiCl₄ and CH₃SiCl₃ may be used to produce a matrix with a high silicon content relative to carbon. This high silicon content facilitates bonding of the silicon carbide to a carbon rich substrate material. Variation of the free silicon content of the deposited material may also be achieved via the composition of the solid particle stream composition, and via control of specific process conditions such as temperature and the mole ratio of hydrogen gas to the CH₃SiCl₃ gas. Reducing the reactor temperature by 50-100° C. from the baseline SiC process increases the silicon ratio by 5-10%. Also, silicon ratio can be reduced further by reducing the mole ratio of hydrogen to CH₃SiCl₃ by 20-30%.

### Vertical Slats

Applicants have developed techniques for producing multiple planar type SiC products during a single production run. Applicants' multi-product technique is shown in FIG. 11. In this case seven 1.0 meter square flat substrate 113A are arranged vertically. SiC mirror elements are produced on both sides of each substrate. With this arrangement, 14 flat mirror elements can be produced simultaneously.

### Metal Boride, Carbide and Nitride Composites

The techniques and reactors described above can be modified slightly to produce metal boride composites, metal carbide composites and metal nitride composites, which are suitable, for example, for ultra high temperature applications. As in the case of the silicon carbide composites, solid particles are entrained in a feed gas stream and the particles are deposited on a substrate along with a matrix material that is vapor deposited from the feed gas. The proposed method is able to maintain the high purity required for ultra-high temperature applications, while achieving a low internal stress in the composites. Table I lists several of these composites along with preferred chemical routes and preferred particle and fiber materials.

Boride Family CVC

Preferred embodiments of the invention involves the production of metal boride ceramics via the general process:
MCl_{4(g)}+2BCl_{3(g)}+5H_{2(g)}→MB₂₍ₛ₎+10HCl_{(g)}
where M=Hf, Zr, Ta, or Ti, BCl₃ is boron trichloride, and H₂ is hydrogen gas. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. This embodiment allows for the production of high purity residual stress free ultra high temperature metal boride ceramic materials.
Carbide Family CVC

Preferred embodiments of the invention involves the production of metal carbide ceramics via the general process:
MCl_{4(g)}+CH₃Cl_{(g)}+H_{2(g)}→MC₍ₛ₎+5HCl_{(g)}
where M=Hf, Zr, to Ta, CH₃Cl is chloromethane, and H₂ is hydrogen gas. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. These embodiments allow for the production of high purity residual stress free ultra high temperature ceramic materials of the carbide family.
Nitride Family

Preferred embodiments of the invention involves the addition of solid particulates to a chemical vapor deposition reaction stream. This invention involves the production of metal nitride ceramics via the general process:
2MCl_{4(g)}+N_{2(g)}+4H_{2(g)}→2MN₍ₛ₎+8HCl_{(g)}
where M=Hf, Zr, to Ta, and N₂ and H₂ are nitrogen and hydrogen gas, respectively. The metal chloride is introduced into the reaction stream by either direct sublimation of the solid, or via in process production of MCl₄ vapor from solid metal and a chlorine containing gas species. To the reaction mixture is added solid micron or nanometer scale particles, whose chemical composition is identical to the metal boride species being formed, or entirely different. These embodiments provide for the production of high purity residual stress free ultra high temperature ceramic materials of the Nitride family.

### Variable Pressure

Net and near-net CVC deposition require effective mass transport of reactants into (and reaction products away from) the topography of the substrate. In certain substrate geometries, the growth of the deposited material results in a loss of mass transport efficiency to certain locations of the substrate. To minimize this result in some cases Applicants utilize variable reaction pressure to optimize process efficiencies and mass transport rates. In the early periods of the deposition, high reactor pressures may be employed because the complex substrate structure is considered “open” and facilitates efficient reactant and product mass transport. As the growth of the deposited material proceeds and significant constriction of reactant (product) flow to (from) certain locations in the structure occurs, the reaction pressure is systematically reduced to increase mass transport rates.

The advantage of this technique lies in the ability to optimize reactant flow rates with regard to mass transport and process efficiency. If high reactant pressures are employed throughout the deposition, certain locations within the complex structure will exhibit deposits that are thinner than desired. However, if low pressures are employed throughout the deposition, including the early periods when the complex structure is “open”, the process efficiency will be reduced due to the enhanced linear velocity of the reactant gases, with consequent losses of reactant to the exhaust system.

### Special Products Using CVC and Reactive Melt Techniques

The chemical vapor composite process and a reactive melt infiltration process can be used in conjunction to produce ceramic products having special shapes such as straight multi-section tubes, angled tubes or “elbows”, and tube sections in the form of a “tee”. Separate ceramic parts can be produced using the chemical vapor composite process. The finished ceramic sections will be ground (such as with either an internal or an external taper) so the individual components will fit tightly together to form the required shapes. The individual components are then bonded using a reactive melt infiltration process. Techniques for joining ceramic section via reactive melt are described in detail in various NASA publications available on the Internet.

### Thin Film Composite Materials

Composites may be produced comprising thin films of material consisting of two or more distinct phases, using physical transport of nanometer-scale particles along with a physical vapor deposition stream(s). Composite thin film materials, i.e., a film containing a mixture of two or more chemically distinct phases, can exhibit a wide variety of interesting properties, such as giant magneto-resistance, enhanced magnetic co-ercivities, and quantum well behavior. These properties arise from the interaction between the different phases, and depend strongly on the grain structure of the film, i.e., grain size, grain boundaries, and arrangement. The common method to form these composite films is to co-deposit material from separate sources by physical vapor deposition (PVD), followed by an anneal to achieve the desired grain structure. However, the annealing step gives limited control over the grain structure and can lead to undesired interdiffusion between the separate phases. The new technique is the formation of composite films by physical transport of nanometer scale particles to a substrate, coincident with a conventional chemical vapor stream. The added particles thus become embedded in the CVD matrix. The key advantage of this method is the ability to precisely control the grain size in each film, with minimal interdiffusion between the phases, since the requirement for high temperature anneal is removed. Various different films can be provided by changing to size and/or number of particles and/or changing the gas chemical or physical properties.

### Designed Stress

In this embodiment, a deliberate sequence of particle types is added to a chemical vapor deposition stream. The materials constituting the different particles are selected for their coefficients of thermal expansion (CTE). The added particle materials may have CTE values higher or lower than that of the matrix phase that is produced by the chemical reaction. The effective CTE of the particle-matrix composite will be a function of the CTE values of the matrix and particle materials. By controlling the volume fraction and type of particle material added to a given layer or local region of the deposited material, the magnitude and distribution of residual stresses in the deposited object can be controlled.

An example application would be the CVC deposition of silicon carbide, wherein the initial particle additives would be low CTE silicon nitride (Si₃N₄). After a selected period of SiC/Si₃N₄ composite growth, the particle additive is changed to high CTE zirconia (ZrO₂). After a selected period of SiC/ZrO₂ growth, the particle additive is changed back to Si₃N₄. Upon cooling, the differential CTE properties of the three composite layers in the deposit result in compressive surface stresses and tensile internal stresses. The effect is analogous to the condition accomplished in tempered glass, where rapid cooling of the surface layers of a molten sheet, followed by slow cooling of the interior results in compressive surface forces and a remarkable enhancement of fracture toughness. The example above assumes the final use temperature is lower than the deposition temperature. The CVC designed stress concept can also be employed to engender compressive surface stresses when the application temperature is higher than the deposit temperature.

### Composite Ferroelectric Materials

Composite ferroelectric material may be produced using selected secondary phase particles with a reactive chemical vapor deposition stream. Ferroelectrics are a class of insulating materials, which can exhibit a spontaneous polarization whose direction can be changed via an applied electric field. The phenomenon is tied to the placement and symmetry of ions in a crystalline lattice, which can be altered by straining the material. A common method of producing ferroelectric materials is metal-organic chemical vapor deposition, which reacts a metal-organic complex at high temperature and under controlled conditions of pressure and gas composition to achieve the desired ferroelectric state. A ferroelectric with altered material properties can be produced by adding a second phase particulate stream to the metal-organic vapor stream. The strain state of the ferroelectric material can be changed by adding a particulate with a different coefficient of thermal expansion (CTE) than the ferroelectric. Upon cool down from the high deposition temperature, the particulate can introduce a tensile or compressive stress on the material, depending on the difference in CTE's between the particle and the ferroelectric. Anticipated benefits could include reduced dielectric loss materials, enhanced dielectric constant, and increased dielectric tunability.

### Porous Structures by Using Removable Particles

This embodiment involves the addition of a particulate stream that includes high aspect ratio fibers or whiskers. The chemical composition of these fibers or whiskers is such that they can be removed from the deposit structure via chemical etching or combustion. The matrix material produced by the chemical vapor deposition process is typically refractory metals or ceramics. Removal of the fiber/whisker components result in a structure of controlled porosity and pore size. The resulting structure can serve as a particle filter device for high temperature, highly corrosive environment applications.

### Transition Joints

In cases where a vapor deposition process is used to deposit a ceramic matrix on a substrate the present invention can be utilized to minimize stresses due to differences in thermal expansion between the substrate and the matrix material. In this case the particle material size and composition can be chosen for adjusting and grading the effective coefficient of thermal expansion of the deposited phase in order to improve bonding of the deposited phase with the substrate phase.

### Bragg Stack SiC Optics

As stated above silicon carbide is a superior material for lightweight mirror applications because of its high stiffness-density ratio, high thermal conductivity and low coefficient of thermal expansion. SiC is particularly favorable for space optics applications because of its resistance to plasma and radiation damage. While SiC is highly reflective in certain limited regions of the infrared spectrum, achieving high reflectivity in other spectral domains requires the addition of a highly reflective coating, for example a metal or dielectric stack structure, either of which may comprise a non-SiC material. Applicants propose to provide a synthesis of a highly reflective Bragg stack via electrochemical etching. The SiC material may be single crystal or polycrystalline and derived via chemical vapor deposition or chemical vapor composites methods. The SiC material may be either n-doped or p-doped to a level sufficient to allow electrochemical etching. The etching would be achieved using an ethanolic hydrofluoric acid solution under either potentiostatic or galvanostatic conditions. Repeated alternating exposures to high and low current densities (or anodic potentials) result in layers of alternating porosity and therefore alternating layers of varying index of refraction. By controlling the anodization current density and etching time for each layer, it is possible to prepare a multiple layer structure, where each layer fulfils a λ/4 condition necessary for high reflectivity over a selected wavelength range. The advantage of this technique lies in the dielectric Bragg stack being comprised of SiC material, rather than another substance with lower radiation and/or plasma tolerance.

### Toughened Ceramics

Preferred embodiments of the present invention can be used to produce toughened ceramics. Fibers and/or whiskers can be added to the reactant gas mixture and injected into a chemical vapor deposition reactor. The fibers and/or the whiskers will be co-deposited to form a ceramic composite. The interweaving fibers serve as the medium to increase the strength of the composite. The added fibers will stop the progression of cracks.

### Annealing for Increased Thermal Conductivity

The basic CVC process produces grains of varying sizes. Applicants have discovered that grain sizes can be increased by adding an annealing step to the CVC process. For example after producing CVC material at the normal deposition temperature of about 1400 degrees C., Applicants increased the temperature in the reactor to 1700 degrees for two hours. Subsequent analysis indicated a significant growth in grain size and an approximately 20 percent increase in thermal conductivity, from about 200 Watts/mK to about 240 Watts/mK.

### Translucent CVC SiC

Applicant's CVC SiC can be made translucent through lowering the pressure to about 10 torr. This reduces the grain size to the point where the material transmits light. This material is potential useful for optical applications, such as conformal optics, missile nose cone, ballistic windows for aircraft and vehicles, and high temperature windows among many other applications. Applicants can produce large transparent surfaces, especially with the 3.37 cubic meter reactor shown in FIG. 1.

### Homogeneous Alloys and Composites

Preferred embodiments of the present invention involves the addition of nanometer sized solid particles to a CVD reaction stream, where the solid particle material and the material deposited through the CVD reaction represent components of a potential homogenous composite. The CVC deposition process results in a composite which is heterogeneous at the molecular scale, but homogenous at the nanometer scale. Because of the high surface—volume ratio of the additive nano-particles, the effective fusion temperature of these particles is lower than that of micron sized particles of the same material. Subsequent heat treatment leads to true homogeneous mixing of the two components. A key advantage of this process is that the composite material can be fabricated at a lower temperature than conventional processes, hence achieving a savings in energy and cost.

### Near Net Shapes Optical Structures

The CVC Process is capable of producing near net shape materials by replicating the surface of the mandrel very precisely. Through the proper selection and preparation of the mandrel material and surface, Applicants can replicate mirrors directly from the mandrel, completely eliminating conventional polishing of the resulting CVC SiC mirror, or at least greatly reducing the extent of the polishing. This is the Holy Grail for high-grade optics and provides important commercial advantages in both cost and quality in the production of mirrors.

### Continuous Controlled Sublimation

Chemical vapor deposition of structural materials requires a precise control over reactant feed rates. When a reactant is a gas at ambient temperatures, a standard gas flow controller can be used. When a reactant is liquid at ambient temperatures and pressures, a liquid vaporizer unit is typically employed, and the control over reactant feed rate is accomplished via control of liquid flow into the vaporizer, and a feedback system through which liquid flow in and vapor flow out maintain an approximately constant vaporizer mass.

If a reactant in a chemical vapor deposition scheme is solid under ambient conditions, reactant feed rate is difficult to control. In preferred embodiments of the present invention, the rate of sublimation is determined by heat and/or carrier gas flow rate into the sublimator unit. The rate of sublimation is monitored by a mass compensator system, namely a device that delivers a powder or a low vapor pressure liquid to a receptacle on the top of the sublimator unit. A scale monitors the mass of the sublimator and the added liquid or powder. A control loop delivers mass data to the heater and/or carrier gas controls. As more solid sublimes and leaves the unit, more compensating powder or liquid is added to maintain a constant mass. The rate at which the compensating powder or liquid is delivered to the receptacle is, under conditions of zero sublimator unit mass change, equivalent to the rate at which the sublimed material is being delivered to the reactor.

It is understood that the preceding description is given merely by way of illustration and not in limitation of the invention and that various modifications may be made thereto without departing from the spirit of the invention as claimed. For example, variations in the toughness and structure of composite articles formed by the method may be achieved by varying process parameters such as reactant gas stream flow and temperature, and the size, shape, and materials of the particles or fibers used as a second phase material. High temperature CVD techniques as well as plasma enhanced CVD (PECVD) techniques can be utilized along with the addition of particles using the techniques described above.

The scope of the invention is indicated by the appended claims, and all changes which come within the meaning and range of equivalency of the claims are intended to be embraced therein.

What is claimed is:

1. A method of a ribbed chemical vapor composite mirror structure, said method comprising the steps of:
A) producing a ribbed chemical vapor composite structure having at least one approximately smooth surface,
B) polishing said approximately smooth surface to achieve a mirror finish.

2. The method as in claim 1 wherein the composite mirror structure is a silicon carbide composite.

3. The method as in claim 2 wherein said structure is produced by milling out a portion of the structure to form ribs.

4. The method as in claim 3 wherein the milling is accomplished using a machine milling process.

5. The method as in claim 3 wherein the milling is accomplished using a water jet milling process.

6. The method as in claim 2 wherein said structure is produced by bonding a plurality of parts to form a rib portion of said ribbed structure.

7. The method as in claim 6 wherein said bonding step is accomplished utilizing a combination of metals to accomplish the bonding.

8. The method as in claim 7 wherein said metals include titanium.

9. The method as in claim 8 where said metals include titanium, platinum, gold and tin.

10. The method as in claim 9 wherein said tin is in the form of a tin solder.

11. The method as in claim 2 wherein said structure includes a fasting element comprised of a low expansion plug soldered into a close fitting hole in said composite structure

12. The method as in claim 2 wherein said plug is comprised of a low expansion carpenter Fe-39Ni material.

13. A method of forming a composite article comprising:
A) providing a ribbed structure comprised of a composite material, said ribbed structure defining empty spaces,
B) fully or partially filing said empty spaces with material thermally stable at temperatures in excess of 1200 degrees C. to define continuous substrate surface on top of said fully or partially filed empty spaces of said ribbed structure, to define a ribbed structure with a smooth continuous substrate surface,
C) inserting said ribbed structure with the smooth continuous substrate surface in a CVC reactor,
D) forming a mixture of particles of a solid phase material and a reactant gas, said reactant gas being thermally activatable to produce chemical vapor deposition (CVD) vapors and other reaction products;
E) thermally activating said ribbed structure with the smooth continuous substrate surface and injecting said mixture of particles of a solid phase material and reactant gas into said reactor such that said gas reacts to produce said CVD vapors that deposit as solids on said smooth continuous substrate surface;
F) co-depositing with said CVD vapors said solid phase material onto said substrate to form composite material at a density within a predetermined density range and an average grain size within a predetermined grain size range, said composite material consisting essentially of (i) a solid matrix formed by chemical vapor deposition of said material from said reactant vapors and (ii) said solid phase material dispersed within said solid matrix;
G) removing the ribbed structure with a smooth continuous substrate surface and the co-deposited composite material from the reactor.

14. The method as in claim 13 wherein said composite material is comprised of a silicon carbide matrix.

15. The method of claim 13 wherein said material thermally stable at temperatures in excess of 1200 degrees C. is comprised of graphite.

16. The method of claim 15 wherein said graphite is in powder form.

17. The method of claim 15 wherein said graphite is in sheet form.

18. The method of claim 16 wherein said graphite is in solid form.
